(19) United States
(12) Patent Application Publication
(10) Pub. No.: US 2024/0234491 A1
(43) Pub. Date: Jul. 11, 2024

(54) VERTICAL SEMICONDUCTOR COMPONENT, IN PARTICULAR VERTICAL TRANSISTOR, WITH MINIMIZED SOURCE-DRAIN LEAKAGE CURRENTS

(71) Applicant: Robert Bosch GmbH, Stuttgart (DE)

(72) Inventors: Dragos Costachescu, Reutlingen (DE); Muhammad Alshahed, Stuttgart (DE); Daniel Krebs, Aufhausen (DE); Humberto Rodriguez Alvarez, Trento (IT)

(21) Appl. No.: 18/402,974

(22) Filed: Jan. 3, 2024

(30) Foreign Application Priority Data
Jan. 10, 2023 (DE) 10 2023 200 115.2

(51) Int. Cl. H01L 29/06; H01L 29/78

(52) U.S. Cl. CPC H01L 29/0603; H01L 29/7802

(57) ABSTRACT

A vertical semiconductor component, in particular a vertical transistor. The component has a vertically lower drain electrode and a semiconductor layer structure arranged vertically above the drain electrode, the semiconductor layer structure having at least one drift layer and a trench-shaped conduction channel, wherein a vertically lower end region of the conduction channel adjoins the drift layer, and wherein a gate electrode is formed vertically above the conduction channel and the conduction channel is conductively connected to a source electrode. The conduction channel has, in an at least partially vertically extending wall portion, a gradation, which is delimited by an upper and a lower boundary surface of the conduction channel such that the wall portion has lateral outer and inner portions which are connected to one another via a lateral intermediate portion. The intermediate portion has a reduced cross-section compared with the outer and inner portions.

### FIELD

The present invention relates to a vertical semiconductor component, in particular a vertical transistor, having a plurality of adjacent cells, the cells having a trench-shaped conduction channel which adjoins a drift layer in a vertically lower end region and which is contacted on at least one lateral side by a source electrode, a gate electrode being formed vertically above the trench-shaped conduction channel and a drain electrode being arranged vertically at the bottom.

### BACKGROUND INFORMATION

Vertical semiconductor components are generally conventional. In these, the final connection electrodes are arranged on two vertically opposite sides of the semiconductor component, in particular of the corresponding semiconductor layer structure for forming a semiconductor component, so that space-saving contacting and a substantially vertical current flow and/or field curve are achieved, which are correspondingly advantageous both for the performance characteristics and for the space consumption of the semiconductor component.

A generic design with a trench-shaped conduction channel, which is contacted vertically at the top and laterally offset by a source electrode and is covered in portions by a vertically upwardly arranged gate electrode, is also described in the prior art. For example, reference can be made to U.S. Pat. No. 10,050,138 B2 as the generic prior art. The generic vertical semiconductor components, in particular transistors, are field-effect transistors or “vertical high-electron mobility transistors (vHEMT).”

In these, for example a transition layer or buffer layer can first be formed on a substrate before a drift layer vertically above it is formed. The drift layer can be covered in regions or in portions by a barrier layer on which, for example, a cover layer is then arranged. By structuring the cover layer and the barrier layer, a correspondingly trench-shaped, for example U-shaped or V-shaped, conduction channel can subsequently be formed by a corresponding layer or conduction layer. An electron supply layer can be formed on the conduction channel, preferably delimited by an intermediate layer. An edge laterally at the side of the conduction channel can be contacted via a source electrode. A gate electrode can be formed in portions on the electron supply layer.

The transistor functionality can be provided by a corresponding circuit or by applying corresponding electrical potentials between the source electrode and drain electrode and between the gate electrode and drain electrode (V_{Ds} and V_{GS}) in such a way that, in the conduction state, a current flows from the source electrode through the conduction channel and the drift layer indirectly or directly to the gate electrode.

In conventional generic semiconductor components, for example according to U.S. Pat. No. 10,050,138 B2, undesirable leakage currents sometimes occur between the source electrode and the drain electrode, in particular with a potential-free gate or a potential-free gate electrode (V_{Gs}=0 volts) and an increasing voltage between the drain electrode and the source electrode (V_{Ds}>0 volts).

These leakage currents occur substantially due to parasitic charge carriers, which can be formed by polarization effects and can be amplified by a possible lack of shielding or depletion effects, in particular in a wall portion of the trench-shaped conduction channel.

### SUMMARY

A semiconductor component according to the present invention, in particular the vertical transistor according to the present invention, may have an advantage that source-drain leakage currents can be effectively minimized or prevented when the gate is potential-free (V_{Gs}=0 volts).

Against the background of the above explanations, according to an example embodiment of the present invention it is therefore provided in the vertical semiconductor component according to the present invention, in particular vertical transistor, having a vertically lower drain electrode and a semiconductor layer structure arranged vertically above the drain electrode, which structure has at least one drift layer and a trench-shaped conduction channel, which adjoins the drift layer in a vertically lower end region and in which a gate electrode is formed above the conduction channel and preferably above an electron supply layer arranged above the conduction channel, and furthermore the conduction channel is conductively connected to a source electrode, that the conduction channel has, in an at least partially vertically extending wall portion, a gradation, which is delimited by an upper and a lower boundary surface of the conduction channel such that the wall portion has a lateral outer portion and a lateral inner portion which are connected to one another via a lateral intermediate portion, wherein the intermediate portion has a reduced cross-section compared with the outer portion and the inner portion.

In other words, this means that a constriction or taper is formed in the wall portion of the trench-shaped conduction channel between the lateral outer portion and the lateral inner portion, which counteracts or at least significantly inhibits a parasitic conduction in the event of a rising or increasing drain-source voltage by causing or improving a corresponding electron depletion or shielding in the lateral intermediate portion or the constriction or taper of the cross-section formed by the gradation of the conduction channel.

The concept of a partially vertically extending wall portion is to be understood vectorially within the meaning of the present description. This means that the wall portion should extend completely vertically or partially vertically, i.e., at an angle, so that a more or less steep flank is formed on both lateral sides of the vertically lower end region of the conduction channel or floor region of the conduction channel in the vertical and possibly lateral direction. Accordingly, this leads to the substantially U-shaped or V-shaped design of the conduction channel in the cross-section of the semiconductor layer structure, wherein the gradation according to the present invention, including the formation of a lateral outer portion, a lateral inner portion and a lateral intermediate portion, interrupts or alters the uniformity of the cross-section of the conduction channel accordingly.

According to a first advantageous embodiment of the present invention, it can be provided that the intermediate portion is designed so as to be planar in the lateral direction, perpendicular to a vertical direction of the semiconductor layer structure. As a result, the shielding effect in the region of the intermediate portion and the resulting avoidance of parasitic conduction or leakage currents can be avoided in a particularly advantageous manner.

According to a further, particularly advantageous embodiment of the present invention, it can be provided that, in the lateral region of the intermediate portion, a lower boundary surface of the conduction channel adjoins a, preferably p-doped, shielding layer. This can also improve or increase the shielding effect or depletion in the lateral intermediate portion and thus avoid or reduce leakage currents between the source electrode and the drain electrode.

According to a further, particularly advantageous embodiment of the semiconductor component of the present invention, it can be provided that the intermediate portion has a maximum layer thickness of 0.7 μm, in particular in a region with a planar, uniform layer thickness.

According to a further particularly advantageous embodiment of the semiconductor component of the present invention, it can also be provided that the trench-shaped conduction channel is contacted on both lateral sides of the gate electrode with a source electrode or a portion of a preferably common source electrode. This enables a two-way current flow from the respective source electrodes or portions of a common source electrode through the conduction channel via the drift layer to the drain electrode.

According to a further, particularly advantageous embodiment of the present invention, it can be provided that a gradation as described above is formed in each partially vertically extending wall portion of a correspondingly trench-shaped conduction channel. Particularly preferably, the semiconductor component, in particular a standard cell of a corresponding semiconductor component, can be designed in such a way that it has a vertically extending axis of symmetry which extends through the gate electrode and a lower end region of the conduction channel arranged vertically below it, wherein substantially the partially vertically extending wall portions of the conduction channel to the right and left of the axis of reflection or symmetry are preferably designed to be mirror images of one another and, in particular, both wall portions of a trench-shaped conduction channel also have corresponding lateral intermediate portions.

In a further, preferred embodiment of the semiconductor component of the present invention, it can be provided that the semiconductor layer structure has at least one layer of gallium nitride or is produced on the basis of gallium nitride as a whole. Gallium nitride is particularly advantageously suited for power semiconductor components due to the low on-resistance (electrical resistance in the conduction state) with simultaneously higher breakdown field strengths/breakdown voltages, wherein the limitation or significant reduction of leakage currents between source electrode and drain electrode according to the present invention support these advantages correspondingly symbiotically or synergistically.

Further advantages, features, and details of the present invention can be found in the following description of preferred embodiments of the present invention and with reference to the figures.

### BRIEF DESCRIPTION OF THE DRAWINGS

FIG. 1 shows a section through a layer structure of a generic VHEMT transistor.

FIG. 2 shows a detail of a section through a layer structure of a semiconductor component according to an example embodiment of the present invention.

### DETAILED DESCRIPTION OF EXAMPLE EMBODIMENTS

Identical elements or elements which have the same function are provided with the same reference signs in the drawings.

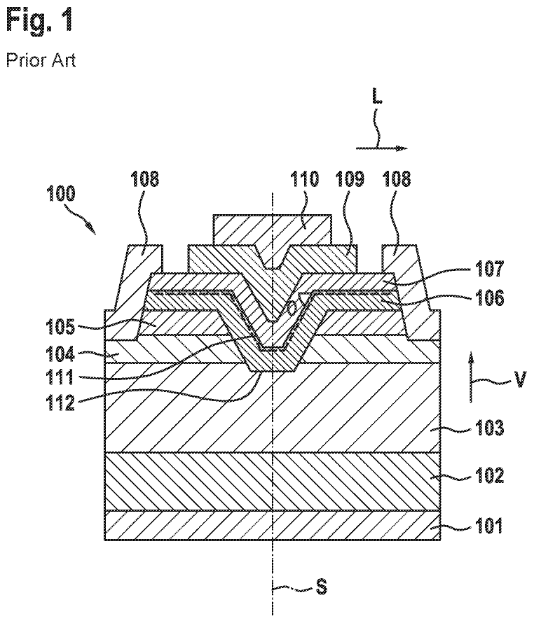

FIG. 1 shows a transistor 100 in a vertical design according to the prior art. A drain electrode 101 is formed at the bottom in a vertical direction V. In the example shown in FIG. 1, a substrate 102, for example a gallium nitride substrate, is arranged above it. However, it is also possible to apply the semiconductor layer structure according to the present invention on another substrate, for example silicon, as heteroepitaxy. As an alternative to the representation of FIG. 1, the substrate 102 can also be partially or completely removed as part of the processing of the semiconductor component, so that the drain electrode 101 is then contacted with the drift layer 103. Both when the substrate 102 is retained and also in an alternative embodiment with partial or complete removal of the substrate 102, further layers not explicitly shown in the representation of FIG. 1 can be arranged between the drain electrode 101 and the drift layer 103. These can be, for example, a contact semiconductor layer, a buffer layer and/or a, preferably multi-layered, transition layer or so-called “engineered layers”. The drift layer 103 is preferably made of n-doped gallium nitride.

In the vertical direction V, a barrier layer 104 and a shielding layer 105 follow vertically above the drift layer 103. The drift layer 103 can, for example, be formed from n-doped gallium nitride or at least include it. The barrier layer 104 can advantageously comprise p-doped gallium nitride. The shielding layer 105 can particularly preferably comprise or be formed from carbon-doped gallium nitride.

In a corresponding structuring of the shielding layer 105 and the barrier layer 104 as well as on an unstructured portion of the shielding layer 105, a generic and conventional trench-shaped conduction channel 106 can be formed. An electron supply layer 107 can be formed or deposited on said channel in the vertical direction V, which also has a corresponding trench-shaped structure or forms a trench-shaped cross-section. The electron supply layer 107 can preferably be formed from undoped aluminum gallium nitride. The conduction channel can be formed from undoped gallium nitride. A further barrier layer (not shown) can be provided between the electron supply layer 107 and the conduction channel.

The electron supply layer 107 can be contacted at the side in the lateral direction via corresponding portions of a source electrode 108. A gate electrode 110 can be formed or deposited above the electron supply layer 107, separated by a further intermediate layer 109, preferably made of p-doped gallium nitride. As can be seen in FIG. 1, the semiconductor layer structure of the transistor 100 is formed substantially mirror-symmetrically to an axis of symmetry S.

The conduction channel 106 forms a planar transition portion to the source electrode 108 on both sides of the axis of symmetry S. As this portion approaches the axis of symmetry S, it merges on both sides into an at least partially vertically extending wall portion 111, which then merges into another planar, vertically lower end portion 112, which extends up to the axis of symmetry S.

Due to parasitic charge carriers in the upper, laterally outer, planar region of the conduction channel 106 and insufficient shielding in the wall portions 111 of the conduction channel 106, unwanted leakage currents can occur with a potential-free gate electrode (V_{GD}=0 volts) if the drain-source voltage increases (V_{Ds}>0 volts).

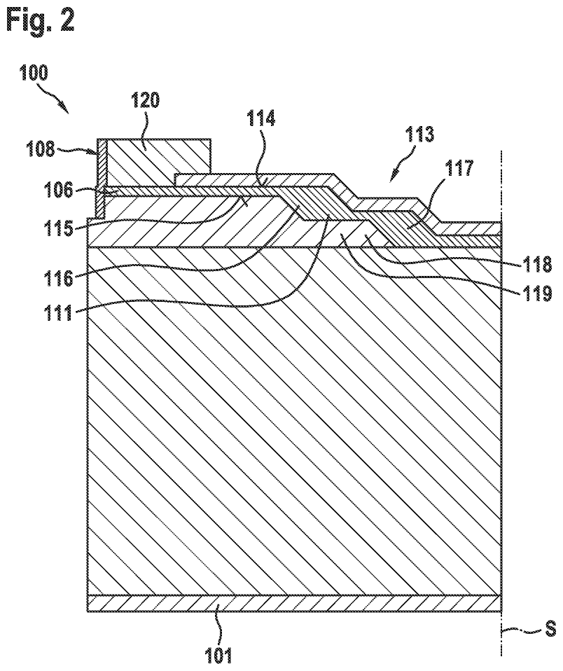

FIG. 2 shows a detail of a section through a semiconductor layer structure according to the present invention. The representation of FIG. 2 is limited to one side, namely the left side of the axis of symmetry S. The entire semiconductor layer structure of the transistor 100 or of a standard cell of a transistor would also be formed on the opposite side of the axis of symmetry S, mirrored accordingly.

It can be seen that the conduction channel 106 contacted via the source electrode 108 in the wall portion 111 has a gradation 113 which is delimited by an upper and a lower boundary surface 114, 115 of the conduction channel 106 such that the wall portion 111 has a lateral outer portion 116 and a lateral inner portion 117, wherein the lateral outer portion 116 and the lateral inner portion 177 are connected to one another via a lateral intermediate portion 118, wherein the intermediate portion 118 has a reduced cross-section compared with the outer portion 116 and the inner portion 117. The narrowing or tapering, including spatial narrowing or tapering, in the intermediate portion 118 can provide more effective shielding against parasitic charge carriers, in particular in the lateral outer portion 116, and can overall prevent or minimize the formation of undesired leakage currents between the source electrode 108 and the drain electrode 101. Additionally, a passivation layer 120 is formed between the source electrode 108 and gate electrode 110. The passivation layer is not shown in the representation of FIG. 1.

FIG. 2 shows that a, preferably p-doped, shielding layer 119 is also formed at least below the intermediate portion 118, which, in addition to the gradation 113, supports effective shielding of the lateral outer portion 116 of the conduction channel 106 and thus effectively prevents or minimizes leakage currents.

The layer thickness of the planarly extending intermediate portion 118 or of the planarly extending part of the intermediate portion 118 can preferably be between 0.03 μm and 0.7 μm. By further reducing the layer thickness of the intermediate portion 118, leakage currents between drain electrode 101 and source electrode 108 can be minimized even better, but the corresponding narrowing or tapering of the intermediate portion 118 also leads to a corresponding increase in the on-resistance (resistance in the conduction state), so that, depending on the application and specification, the layer thickness or the cross-section of the intermediate portion 118 is particularly preferably selected in such a way that the best possible combination of low on-resistance and sufficient freedom from leakage is ensured.

1.-6. (canceled)

7. A vertical semiconductor component, comprising:
a vertically lower drain electrode;
a semiconductor layer structure arranged vertically above the drain electrode, wherein the semiconductor layer structure has at least one drift layer and a trench-shaped conduction channel, wherein a vertically lower end region of the conduction channel adjoins the drift layer, and wherein a gate electrode is formed vertically above the conduction channel and the conduction channel is conductively connected to a source electrode;
wherein the conduction channel has, in an at least partially vertically extending wall portion, a gradation, which is delimited by an upper and a lower boundary surface of the conduction channel such that the wall portion has a lateral outer portion and a lateral inner portion which are connected to one another via a lateral intermediate portion, wherein the intermediate portion has a reduced cross-section compared with the outer portion and the inner portion.

8. The semiconductor component according to claim 7, wherein the semiconductor component is a vertical transistor.

9. The semiconductor component according to claim 7, wherein the intermediate portion is configured so as to be planar in a lateral direction, perpendicular to a vertical direction.

10. The semiconductor component according to claim 7, wherein, in the lateral region of the intermediate portion, a lower boundary surface of the conduction channel adjoins a p-doped shielding layer.

11. The semiconductor component according to claim 7, wherein the intermediate portion has a maximum layer thickness of 0.7 μm.

12. The semiconductor component according to claim 7, wherein the conduction channel is contacted on both lateral sides of the gate electrode with a source electrode or a portion of a source electrode.

13. The semiconductor component according to claim 7, wherein the semiconductor layer structure has at least one gallium nitride layer or is produced based on gallium nitride.
